(19) United States
(12) Patent Application Publication
(10) Pub. No.: US 2026/0322347 A1
(43) Pub. Date: Oct. 15, 2026

(54) ACOUSTIC WAVE DEVICE

(71) Applicant: Murata Manufacturing Co., Ltd., Nagaokakyo-shi (JP)

(72) Inventor: Katsuya DAIMON, Nagaokakyo-shi (JP)

(21) Appl. No.: 19/466,964

(22) Filed: Feb. 2, 2026

(30) Foreign Application Priority Data
Feb. 3, 2025 (JP) 2025-016134

(51) Int. Cl. H03H 9/02; H03H 9/145; H03H 9/25

(52) U.S. Cl. CPC H03H 9/02574; H03H 9/02559; H03H 9/02637; H03H 9/145; H03H 9/25

(57) ABSTRACT

An acoustic wave device includes first and second acoustic wave resonators. The first acoustic wave resonator includes a first piezoelectric layer, a second piezoelectric layer on the first piezoelectric layer, a first IDT electrode on the second piezoelectric layer and including electrode fingers, and a first dielectric film on the second piezoelectric layer to cover the first IDT electrode. The second acoustic wave resonator shares the first piezoelectric layer with the first acoustic wave resonator, and includes a second IDT electrode provided directly or indirectly on the first piezoelectric layer and including electrode fingers, and a second dielectric film provided directly or indirectly on the first piezoelectric layer to cover the second IDT electrode. Distances between the first piezoelectric layer and the first IDT electrode, and between the first piezoelectric layer and the second IDT electrode, are different. The first and second piezoelectric layers have different polarization directions.

### CROSS REFERENCE TO RELATED APPLICATIONS

This application claims the benefit of priority to Japanese Patent Application No. 2025-016134 filed on Feb. 3, 2025. The entire contents of this application are hereby incorporated herein by reference.

### BACKGROUND OF THE INVENTION

### 1. Field of the Invention

The present invention relates to acoustic wave devices.

### 2. Description of the Related Art

Conventionally, acoustic wave devices are widely used in filters of cellular phones and the like. International Publication No. 2021/125013 discloses multiple examples of the acoustic wave devices. One example of the acoustic wave device includes a multilayer body including two layers of piezoelectric films on a support. An interdigital transducer (IDT) electrode is provided on the multilayer body. In an acoustic wave device provided as a comparative example, a single layer of a piezoelectric film is provided on a support. An IDT electrode is provided on the piezoelectric film.

### SUMMARY OF THE INVENTION

The present inventor has discovered that an acoustic wave resonator including one layer of a piezoelectric film and an acoustic wave resonator including two layers of piezoelectric films may be used in a common single filter device. However, the present inventor has also discovered that using both acoustic wave resonators in one filter device makes it difficult to suppress an unnecessary wave because both acoustic wave resonators have different cut-angles of the piezoelectric films at which an unnecessary wave may be suppressed. The present has discovered that, also in a case in which thicknesses of piezoelectric films are different between a plurality of acoustic wave resonators each including two layers of piezoelectric films, cut-angles of the piezoelectric films that may suppress an unnecessary wave differ between the plurality of acoustic wave resonators. Therefore, suppressing an unnecessary wave is difficult also when such a plurality of acoustic wave resonators are used in one filter device.

Example embodiments of the present invention provide acoustic wave devices each capable of suppressing an unnecessary wave in a plurality of acoustic wave resonators.

An acoustic wave device according to an example embodiment of the present invention includes at least one first acoustic wave resonator and at least one second acoustic wave resonator. The at least one first acoustic wave resonator includes a first piezoelectric layer, a second piezoelectric layer provided on the first piezoelectric layer, a first IDT electrode provided on the second piezoelectric layer and including a plurality of electrode fingers, and a first dielectric film provided on the second piezoelectric layer to cover the first IDT electrode. The at least one second acoustic wave resonator is at least one acoustic wave resonator sharing the first piezoelectric layer with the first acoustic wave resonator. The second acoustic wave resonator includes a second IDT electrode provided directly or indirectly on the first piezoelectric layer and including a plurality of electrode fingers, and a second dielectric film provided directly or indirectly on the first piezoelectric layer to cover the second IDT electrode. A distance between the first piezoelectric layer and the first IDT electrode is different from a distance between the first piezoelectric layer and the second IDT electrode. A polarization direction of the first piezoelectric layer is different from a polarization direction of the second piezoelectric layer. The first IDT electrode is embedded in the first dielectric film and the second IDT electrode is embedded in the second dielectric film.

The acoustic wave devices according to example embodiments of the present invention suppress an unnecessary wave in the plurality of acoustic wave resonators.

The above and other elements, features, steps, characteristics and advantages of the present invention will become more apparent from the following detailed description of the example embodiments with reference to the attached drawings.

### BRIEF DESCRIPTION OF THE DRAWINGS

FIG. 1 is a schematic plan view of an acoustic wave device according to a first example embodiment of the present invention.

FIG. 2 is a schematic elevational cross-sectional view of surroundings of a pair of electrode fingers of a first acoustic wave resonator and surroundings of a pair of electrode fingers of a second acoustic wave resonator according to the first example embodiment of the present invention.

FIG. 3 is a schematic elevational cross-sectional view of surroundings of a pair of electrode fingers of an acoustic wave resonator of a comparative example.

FIG. 4 is a diagram illustrating a relationship between a thickness of a second piezoelectric layer, a second Euler angle of a first piezoelectric layer, and a phase of a Rayleigh wave of the acoustic wave resonator of the comparative example.

FIG. 5 is a schematic elevational cross-sectional view of surroundings of a pair of electrode fingers of an acoustic wave resonator having the same configuration as a configuration of the first acoustic wave resonator and the second acoustic wave resonator of the first example embodiment of the present invention.

FIG. 6 is a diagram illustrating a relationship between the thickness of the second piezoelectric layer, the second Euler angle of the first piezoelectric layer, and the phase of the Rayleigh wave of the acoustic wave resonator having the same configuration as the configuration of the first acoustic wave resonator and the second acoustic wave resonator of the first example embodiment of the present invention.

FIG. 7 is a diagram illustrating a relationship between the thickness of the second piezoelectric layer, the second Euler angle of the first piezoelectric layer, and a fractional bandwidth of the acoustic wave resonator having the same configuration as the configuration of the first acoustic wave resonator and the second acoustic wave resonator of the first example embodiment of the present invention.

FIG. 8 is a diagram illustrating a relationship between a thickness of a portion positioned on a first IDT electrode in a first layer and a phase of a higher-order mode in a first dielectric film according to the first example embodiment of the present invention.

FIG. 9 is a schematic elevational cross-sectional view of surroundings of a pair of electrode fingers of a first acoustic wave resonator and surroundings of a pair of electrode fingers of a second acoustic wave resonator according to a second example embodiment of the present invention.

FIG. 10 is a diagram illustrating a relationship between the thickness of the second piezoelectric layer, the second Euler angle of the first piezoelectric layer, and the phase of the Rayleigh wave of the first acoustic wave resonator and the second acoustic wave resonator according to the second example embodiment of the present invention.

FIG. 11 is a partially enlarged view of FIG. 10.

### DETAILED DESCRIPTION OF THE EXAMPLE EMBODIMENTS

Hereinafter, specific example embodiments of the present invention are described with reference to the drawings.

Note that each example embodiment described herein is illustrative, and configurations of different example embodiments can partly be replaced from or combined with one another.

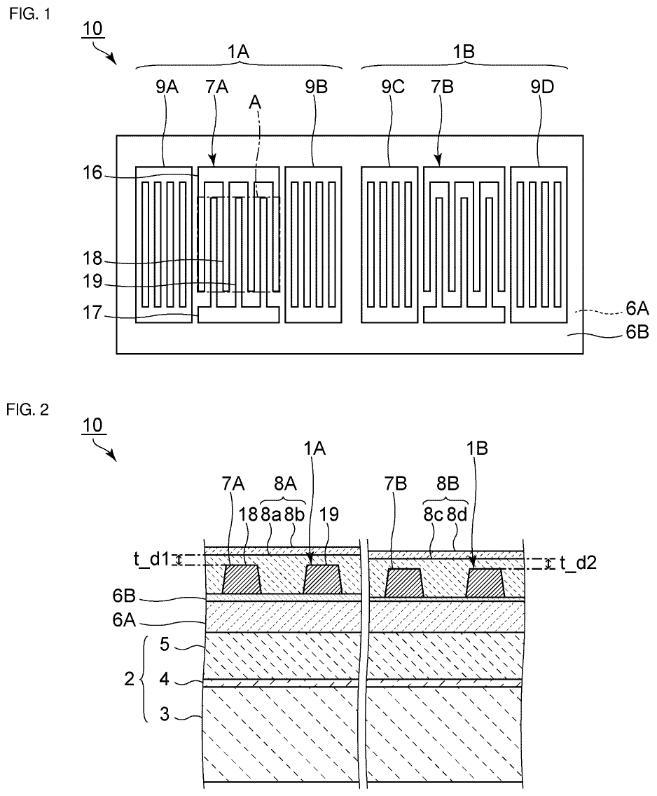

FIG. 1 is a schematic plan view of an acoustic wave device according to a first example embodiment of the present invention. In FIG. 1, a first dielectric film and a second dielectric film described later are omitted.

An acoustic wave device 10 is used as a portion of a filter device. The acoustic wave device 10 includes a plurality of acoustic wave resonators. Acoustic wave devices according to example embodiments of the present invention may be a filter device. A configuration of the acoustic wave device 10 will be described below.

The acoustic wave device 10 includes one first acoustic wave resonator 1A and one second acoustic wave resonator 1B. Note that the acoustic wave device 10 may include at least one first acoustic wave resonator 1A and at least one second acoustic wave resonator 1B.

The first acoustic wave resonator 1A includes a first IDT electrode 7A. The first IDT electrode 7A includes a pair of busbars and a plurality of electrode fingers. The one pair of busbars are, specifically, a first busbar 16 and a second busbar 17. The first busbar 16 and the second busbar 17 are opposed to one another. The plurality of electrode fingers are, specifically, a plurality of first electrode fingers 18 and a plurality of second electrode fingers 19. One ends of the plurality of first electrode fingers 18 are connected to the first busbar 16. One ends of the plurality of second electrode fingers 19 are connected to the second busbar 17. The plurality of first electrode fingers 18 and the plurality of second electrode fingers 19 interdigitate with one another. The first electrode finger 18 and the second electrode finger 19 are connected to electric potentials different from one another. Hereinafter, the first electrode finger 18 and the second electrode finger 19 may simply be referred to as an electrode finger in a collective way.

The second acoustic wave resonator 1B includes a second IDT electrode 7B. Similarly to the first IDT electrode 7A, the second IDT electrode 7B also includes a pair of busbars and a plurality of electrode fingers. Hereinafter, assume that a direction in which the plurality of electrode fingers extend is an electrode-finger extension direction and a direction orthogonal to the electrode-finger extension direction is an electrode-finger orthogonal direction. In the acoustic wave device 10, the electrode-finger extension direction of the first acoustic wave resonator 1A and the electrode-finger extension direction of the second acoustic wave resonator 1B are parallel to one another. The electrode-finger extension direction of the first acoustic wave resonator 1A and the electrode-finger extension direction of the second acoustic wave resonator 1B are not necessarily parallel to one another.

FIG. 2 is a schematic elevational cross-sectional view of surroundings of a pair of electrode fingers of a first acoustic wave resonator and surroundings of a pair of electrode fingers of a second acoustic wave resonator according to the first example embodiment.

The first acoustic wave resonator 1A includes a support 2, a first piezoelectric layer 6A, a second piezoelectric layer 6B, the first IDT electrode 7A, and a first dielectric film 8A. The support 2 includes a support substrate 3, a first intermediate layer 4, and a second intermediate layer 5. The first intermediate layer 4 is provided on the support substrate 3. The second intermediate layer 5 is provided on the first intermediate layer 4. The configuration of the support 2 is not limited to that described above. For example, the support 2 may include only the support substrate 3.

The first piezoelectric layer 6A is provided on the second intermediate layer 5 of the support 2. The second piezoelectric layer 6B is provided on the first piezoelectric layer 6A. The first IDT electrode 7A is provided on the second piezoelectric layer 6B. The first dielectric film 8A is provided on the second piezoelectric layer 6B to cover the first IDT electrode 7A. The first IDT electrode 7A is embedded in the first dielectric film 8A. Herein, the state in which the IDT electrode provided on the piezoelectric layer is embedded in the dielectric film indicates that the thickness of the dielectric film is larger than the thickness of the IDT electrode and the dielectric film is provided on the piezoelectric layer to cover the IDT electrode. The thickness of the dielectric film as used herein indicates a distance from a surface of the dielectric film in contact with the piezoelectric layer to a surface of the dielectric film opposed to the aforementioned surface.

The second acoustic wave resonator 1B shares the support 2, the first piezoelectric layer 6A, and the second piezoelectric layer 6B with the first acoustic wave resonator 1A. The second acoustic wave resonator 1B includes the second IDT electrode 7B and a second dielectric film 8B. In the second acoustic wave resonator 1B, the second IDT electrode 7B is provided on the second piezoelectric layer 6B. The second dielectric film 8B is provided on the second piezoelectric layer 6B to cover the second IDT electrode 7B. The second IDT electrode 7B is embedded in the second dielectric film 8B.

In the first acoustic wave resonator 1A, alternating-current voltage is applied to the first IDT electrode 7A to excite an acoustic wave. In the second acoustic wave resonator 1B, alternating-current voltage is applied to the second IDT electrode 7B to excite an acoustic wave. In this example embodiment, a Rayleigh wave is an unnecessary wave.

As illustrated in FIG. 2, the first IDT electrode 7A and the second IDT electrode 7B are opposed to the first piezoelectric layer 6A with the second piezoelectric layer 6B interposed therebetween. A distance between the first piezoelectric layer 6A and the first IDT electrode 7A is a thickness of a portion of the second piezoelectric layer 6B provided with the first IDT electrode 7A. A distance between the first piezoelectric layer 6A and the second IDT electrode 7B is a thickness of a portion of the second piezoelectric layer 6B provided with the second IDT electrode 7B. In the second piezoelectric layer 6B, the thickness of the portion provided with the first IDT electrode 7A is different from the thickness of the portion provided with the second IDT electrode 7B. Therefore, the distance between the first piezoelectric layer 6A and the first IDT electrode 7A is different from the distance between the first piezoelectric layer 6A and the second IDT electrode 7B.

In this example embodiment, the second IDT electrode 7B and the second dielectric film 8B are provided indirectly on the first piezoelectric layer 6A with the second piezoelectric layer 6B interposed therebetween. Note that the second IDT electrode 7B may be provided directly on the first piezoelectric layer 6A. The second dielectric film 8B may be provided directly on the first piezoelectric layer 6A to cover the second IDT electrode 7B. In an example embodiment of the present invention, the second IDT electrode 7B and the second dielectric film 8B may be provided directly or indirectly on the first piezoelectric layer 6A.

In the acoustic wave device 10, assuming that a wavelength defined by an electrode finger pitch of the first IDT electrode 7A is λ₁ and a wavelength defined by an electrode finger pitch of the second IDT electrode 7B is λ₂, λ₁=λ₂ is established. The electrode finger pitch is a distance of center to center spacing between the adjacent electrode fingers in the electrode-finger orthogonal direction. In an example embodiment of the present invention, λ₁≠λ₂ may be established. Alternatively, for example, in a case in which the acoustic wave device 10 includes a plurality of first acoustic wave resonators 1A, the plurality of first acoustic wave resonators 1A may have wavelengths λ₁ different from one another. In a case in which the acoustic wave device 10 includes a plurality of second acoustic wave resonators 1B, the plurality of second acoustic wave resonators 1B may have wavelengths λ₂ different from one another.

Each of the first IDT electrode 7A and the second IDT electrode 7B includes a plurality of metal layers. Each of the first IDT electrode 7A and the second IDT electrode 7B includes a main electrode layer. Herein, the main electrode layer is a metal layer that is more than about 50 wt %, that is, above about 50 wt % of all the metal layers, for example. In the first IDT electrode 7A, specifically, a NiCr layer, a Pt layer, a Ti layer, an Al layer, and a Ti layer are stacked in this order from the second piezoelectric layer 6B side. The main electrode layer of the first IDT electrode 7A is the Pt layer. A stacking configuration and a main electrode layer of the second IDT electrode 7B are the same as the stacking configuration and the main electrode layer of the first IDT electrode 7A.

Note that the stacking configuration and the main electrode layer of each of the first IDT electrode 7A and the second IDT electrode 7B are not limited to those described above. Each of the first IDT electrode 7A and the second IDT electrode 7B may include at least one metal layer.

Referring back to FIG. 1, when seen in the electrode-finger orthogonal direction, a region where the adjacent electrode fingers of the first IDT electrode 7A overlap one another is an intersecting region A of the first acoustic wave resonator 1A. The intersecting region A is a region of the first piezoelectric layer 6A and the second piezoelectric layer 6B, which is defined based on the configuration of the first IDT electrode 7A. Meanwhile, when seen in the electrode-finger orthogonal direction, a region where the adjacent electrode fingers of the second IDT electrode 7B overlap one another is an intersecting region of the second acoustic wave resonator 1B. The intersecting region is a region of the first piezoelectric layer 6A and the second piezoelectric layer 6B, which is defined based on the configuration of the second IDT electrode 7B.

Assuming that a dimension of the intersecting region in the electrode-finger extension direction is an intersecting width, the intersecting width of the first acoustic wave resonator 1A and the intersecting width of the second acoustic wave resonator 1B are the same as one another. Note that intersecting widths of the plurality of acoustic wave resonators in the acoustic wave device 10 may be different from one another.

The first acoustic wave resonator 1A includes a pair of reflectors. The pair of reflectors of the first acoustic wave resonator 1A are, specifically, a reflector 9A and a reflector 9B. The reflector 9A and the reflector 9B are opposed to one another with the first IDT electrode 7A interposed therebetween. Similarly, the second acoustic wave resonator 1B includes a pair of reflectors. The pair of reflectors of the second acoustic wave resonator 1B are, specifically, a reflector 9C and a reflector 9D. The reflector 9C and the reflector 9D are opposed to one another with the second IDT electrode 7B interposed therebetween. Every reflector is provided on the second piezoelectric layer 6B.

The reflector 9A includes a pair of reflector busbars and a plurality of reflector electrode fingers. The pair of reflector busbars are opposed to one another. One ends of the plurality of reflector electrode fingers are connected to one of the reflector busbars. The other ends of the plurality of reflector electrode fingers are connected to the other one of the reflector busbars. The reflector 9B, the reflector 9C, and the reflector 9D have the same configurations as that of the reflector 9A.

As illustrated in FIG. 2, in this example embodiment, each of the first dielectric film 8A and the second dielectric film 8B is a multilayer film. Specifically, the first dielectric film 8A includes a first layer 8a and a second layer 8b. The first layer 8a is provided on the second piezoelectric layer 6B. The second layer 8b is provided on the first layer 8a. The first IDT electrode 7A is embedded in the first layer 8a. Meanwhile, the second dielectric film 8B includes a first layer 8c and a second layer 8d. The first layer 8c is provided on the second piezoelectric layer 6B. The second layer 8d is provided on the first layer 8c. The second IDT electrode 7B is embedded in the first layer 8c.

The first dielectric film 8A and the second dielectric film 8B are made of the same material and provided integrally. Specifically, the first layer 8a of the first dielectric film 8A and the first layer 8c of the second dielectric film 8B are made of the same material and provided integrally. Similarly, the second layer 8b of the first dielectric film 8A and the second layer 8d of the second dielectric film 8B are also made of the same material and provided integrally.

More specifically, silicon oxide is used as the material for the first layer 8a of the first dielectric film 8A and the first layer 8c of the second dielectric film 8B. Silicon nitride is used as the material for the second layer 8b of the first dielectric film 8A and the second layer 8d of the second dielectric film 8B. The material for each layer of the first dielectric film 8A and the second dielectric film 8B is not limited to that described above. Alternatively, each of the first dielectric film 8A and the second dielectric film 8B may be a single-layered dielectric film.

In the dielectric film including the first dielectric film 8A and the second dielectric film 8B integrated together, a portion covering the first IDT electrode 7A is the first dielectric film 8A. In the above-described dielectric film, a portion covering the second IDT electrode 7B is the second dielectric film 8B. Note that the first dielectric film 8A and the second dielectric film 8B may be provided separately.

In this example embodiment, a combination of materials of the support substrate 3/the first intermediate layer 4/the second intermediate layer 5/the first piezoelectric layer 6A/the second piezoelectric layer 6B as a multilayer body is silicon/silicon nitride/silicon oxide/lithium niobate/lithium niobate. The materials for the support substrate 3, the first intermediate layer 4, the second intermediate layer 5, the first piezoelectric layer 6A, and the second piezoelectric layer 6B are not limited to those described above.

A polarization direction of the first piezoelectric layer 6A is different from a polarization direction of the second piezoelectric layer 6B. More specifically, in this example embodiment, the polarization direction of the first piezoelectric layer 6A and the polarization direction of the second piezoelectric layer 6B are mutually inverted.

Here, at any Euler angles (φ, θ, ψ), the angle φ is a first Euler angle, the angle θ is a second Euler angle, and the angle ψ is a third Euler angle. Herein, when two piezoelectric layers have polarization directions mutually inverted, a difference of the second Euler angle θ between the two piezoelectric layers is within a range of about 180 °±5 °, for example. Hereinafter, assume that the Euler angles of the first piezoelectric layer 6A are (φ1, θ1, ψ1), and the Euler angles of the second piezoelectric layer 6B are (φ2, θ2, ψ2). A difference between the angle θ1, which is the second Euler angle in the Euler angles (φ1, θ1, ψ1) of the first piezoelectric layer 6A, and the angle θ2, which is the second Euler angle in the Euler angles (φ2, θ2, ψ2) of the second piezoelectric layer 6B, is within the range of about 180 °±5 °, for example. Note that the difference between the second Euler angle θ1 and the second Euler angle θ2 is not limited to that described above.

A feature of this example embodiment is to include the following configurations. 1) The distance between the first piezoelectric layer 6A and the first IDT electrode 7A is different from the distance between the first piezoelectric layer 6A and the second IDT electrode 7B. 2) The polarization direction of the first piezoelectric layer 6A is different from the polarization direction of the second piezoelectric layer 6B. 3) The first IDT electrode 7A is embedded in the first dielectric film 8A, and the second IDT electrode 7B is embedded in the second dielectric film 8B. Thus, an unnecessary wave can be suppressed in the first acoustic wave resonator 1A and the second acoustic wave resonator 1B as the plurality of acoustic wave resonators. Details thereof will be described below with reference to an acoustic wave resonator of a comparative example.

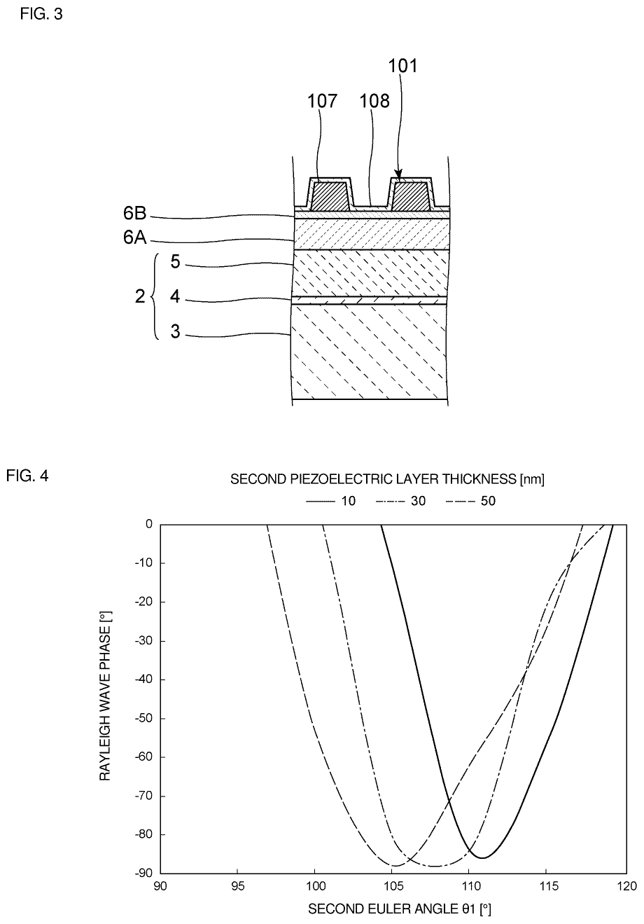

As illustrated in FIG. 3, an acoustic wave resonator 101 of the comparative example is different from the first acoustic wave resonator 1A of the first example embodiment in that an IDT electrode 107 is not embedded in a dielectric film 108. The acoustic wave resonator 101 of the comparative example is different from the first acoustic wave resonator 1A of the first example embodiment also in that the dielectric film 108 is a single-layered dielectric film.

Specifically, in the acoustic wave resonator 101 of the comparative example, similarly to the first example embodiment, the support 2, the first piezoelectric layer 6A, and the second piezoelectric layer 6B are stacked. On the other hand, the comparative example is different from the first example embodiment in that the thickness of the dielectric film 108 is smaller than the thickness of the IDT electrode 107. The dielectric film 108 is provided on the second piezoelectric layer 6B to cover the IDT electrode 107. That is, the IDT electrode 107 is covered by the dielectric film 108 but is not embedded in the dielectric film 108.

In the acoustic wave resonator 101 of the comparative example, a relationship between the second Euler angle θ1 of the first piezoelectric layer 6A and a phase of the Rayleigh wave, which was an unnecessary wave, was simulated for each different thickness of the second piezoelectric layer 6B. In the examination, a relationship between the second Euler angle θ1 of the first piezoelectric layer 6A and the second Euler angle θ2 of the second piezoelectric layer 6B is θ2 =about θ1-180 °, for example. In the examination, the thickness of the second piezoelectric layer 6B of the acoustic wave resonator 101 was about 10 nm, about 30 nm, or about 50 nm, for example.

FIG. 4 is a diagram illustrating the relationship between the thickness of the second piezoelectric layer, the second Euler angle of the first piezoelectric layer, and the phase of the Rayleigh wave of the acoustic wave resonator of the comparative example.

As illustrated in FIG. 4, in the comparative example, the relationship between the second Euler angle θ1 and the phase of the Rayleigh wave largely differs as the thickness of the second piezoelectric layer 6B changes every 20 nm. Therefore, for example, in a case in which the acoustic wave device includes a plurality of acoustic wave resonators 101 of the comparative example with different thicknesses of the second piezoelectric layer 6B, it is difficult to suppress the Rayleigh wave in all the acoustic wave resonators 101.

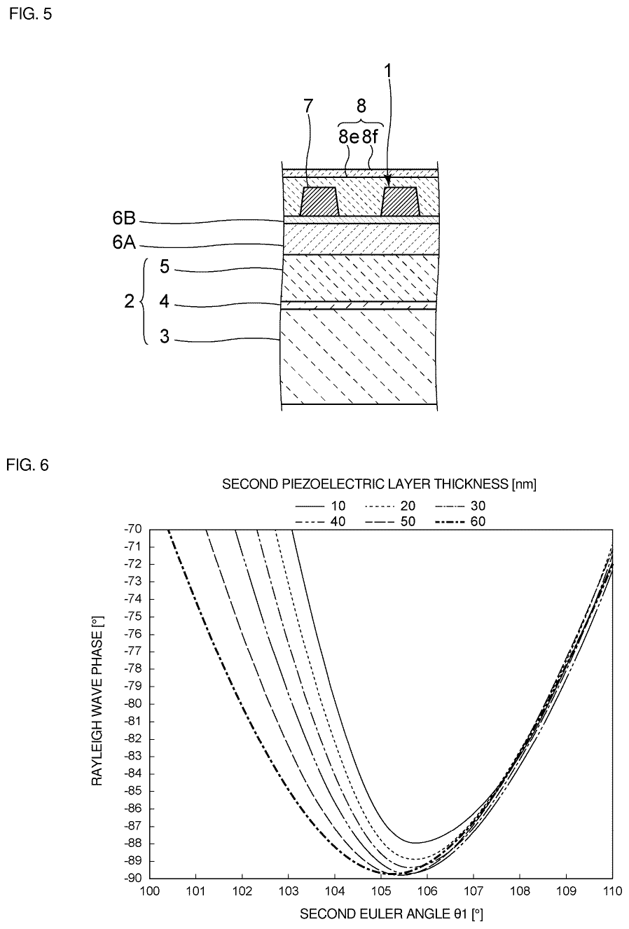

On the other hand, in the first example embodiment, the Rayleigh wave, which is an unnecessary wave, can be suppressed in both of the first acoustic wave resonator 1A and the second acoustic wave resonator 1B with different thicknesses of the second piezoelectric layer 6B. This will be described with reference to an acoustic wave resonator 1 illustrated in FIG. 5. The acoustic wave resonator 1 has the same configuration as that of the first acoustic wave resonator 1A and the second acoustic wave resonator 1B illustrated in FIG. 2.

Specifically, in the acoustic wave resonator 1 illustrated in FIG. 5, the support substrate 3, the first intermediate layer 4, the second intermediate layer 5, the first piezoelectric layer 6A, and the second piezoelectric layer 6B are stacked in this order. An IDT electrode 7 is provided on the second piezoelectric layer 6B. A dielectric film 8 is provided on the second piezoelectric layer 6B to cover the IDT electrode 7. The dielectric film 8 is a multilayer body including a first layer 8e and a second layer 8f. The IDT electrode 7 is embedded in the first layer 8e. The second layer 8f is provided on the first layer 8e.

In the acoustic wave resonator 1, a relationship between the second Euler angle θ1 of the first piezoelectric layer 6A and the phase of the Rayleigh wave was simulated for each different thickness of the second piezoelectric layer 6B. Examples of design parameters of the acoustic wave resonator 1 may be as follows. Assume that, in the acoustic wave resonator 1, a wavelength defined by an electrode finger pitch is λ. Herein, unless otherwise specified, the thickness of the first layer of the dielectric film is the entire thickness of the first layer. Note that, as will be described later, a partial thickness of the first layer may be used as an example parameter.

Support substrate: material . . . Si, thickness . . . 100 μm, azimuth . . . (111), Euler angles (φ, θ, ψ) . . . (−45 °, −54.7 °, 73 °)

First intermediate layer: material . . . SiN, thickness . . . 50 nm

Second intermediate layer: material . . . SiO₂, thickness . . . 400 nm

First piezoelectric layer: material . . . LiNbO₃, thickness . . . 300 nm, Euler angles (φ1, θ1, ψ1) . . . (0 °, θ1, 0 °), second Euler angle θ1 . . . changed every 0.5 °within a range of 90 °or more and 160 °or less

Second piezoelectric layer: material . . . LiNbO₃, thickness . . . changed every 10 nm within a range of 10 nm or more and 60 nm or less, Euler angles (φ2, θ2, ψ2) . . . (0 °, θ2, 0 °), second Euler angle θ2 . . . θ1-180 °and changed every 0.5 °within a range of −90 °or more and −20 °or less

IDT electrode: material . . . NiCr/Pt/Ti/Al/Ti from the second piezoelectric layer side, thickness . . . 10 nm/30 nm/30 nm/150 nm/10 nm from the second piezoelectric layer side, duty ratio . . . 0.5, the number of pairs of electrode fingers . . . 100 pairs

Wavelength λ: 1.5 μm

Intersecting width: 20 λ

First layer of dielectric film: material . . . SiO₂, thickness . . . 330 nm

Second layer of dielectric film: material . . . SiN, thickness 30 nm

FIG. 6 is a diagram illustrating a relationship between the thickness of the second piezoelectric layer, the second Euler angle of the first piezoelectric layer, and the phase of the Rayleigh wave of the acoustic wave resonator having the same configuration as the configuration of the first acoustic wave resonator and the second acoustic wave resonator of the first example embodiment.

As illustrated in FIG. 6, even when the thickness of the second piezoelectric layer 6B changes, the second Euler angle θ1 of the first piezoelectric layer 6A at which the phase of the Rayleigh wave becomes a local minimum value is approximately 105 °to 106 °, for example, and is nearly unchanged. Strictly speaking, as the thickness of the second piezoelectric layer 6B increases, the second Euler angle θ1 of the first piezoelectric layer 6A at which the phase of the Rayleigh wave becomes the local minimum value slightly decreases. However, a change in the second Euler angle θ1 is less than about 1 °, for example. Therefore, in a case in which the acoustic wave device includes a plurality of acoustic wave resonators 1 with different thicknesses of the second piezoelectric layer 6B, the Rayleigh wave, which is an unnecessary wave, can be suppressed in every acoustic wave resonator 1.

In the first example embodiment, the acoustic wave resonator 1 with a relatively large thickness of the second piezoelectric layer 6B is the first acoustic wave resonator 1A. The acoustic wave resonator 1 with a relatively small thickness of the second piezoelectric layer 6B is the second acoustic wave resonator 1B. As a result, the Rayleigh wave, which is an unnecessary wave, can be suppressed in the first acoustic wave resonator 1A and the second acoustic wave resonator 1B as the plurality of acoustic wave resonators in the acoustic wave device 10.

Meanwhile, the thickness of the first dielectric film 8A can be adjusted to adjust a resonant frequency of the first acoustic wave resonator 1A. Similarly, the thickness of the second dielectric film 8B can be adjusted to adjust a resonant frequency of the second acoustic wave resonator 1B. The thickness of the first dielectric film 8A may be different from the thickness of the second dielectric film 8B. In this case, the resonant frequencies of the first acoustic wave resonator 1A and the second acoustic wave resonator 1B can be adjusted individually.

As described above, the first acoustic wave resonator 1A and the second acoustic wave resonator 1B have different thicknesses of the second piezoelectric layer 6B. Therefore, fractional bandwidths of the first acoustic wave resonator 1A and the second acoustic wave resonator 1B are different from one another. The fractional bandwidth is represented by (|fa-fr|/fr)×100 [%], where a resonant frequency is fr and an anti-resonant frequency is fa. For example, when the acoustic wave device 10 is used in the filter device, the thickness of the second piezoelectric layer 6B can be adjusted in accordance with the resonant frequency or an anti-resonant frequency of the first acoustic wave resonator 1A to adjust the fractional bandwidth. The same applies to the second acoustic wave resonator 1B. The acoustic wave resonator 1 illustrated in FIG. 5 will be referred to in order to describe that the fractional bandwidths of the first acoustic wave resonator 1A and the second acoustic wave resonator 1B are adjustable.

In the acoustic wave resonator 1, a relationship between the second Euler angle θ1 of the first piezoelectric layer 6A and the fractional bandwidth was simulated for each different thickness of the second piezoelectric layer 6B. Example design parameters of the acoustic wave resonator 1 were the same as the example design parameters of the acoustic wave resonator 1 in the examination illustrated in FIG. 6.

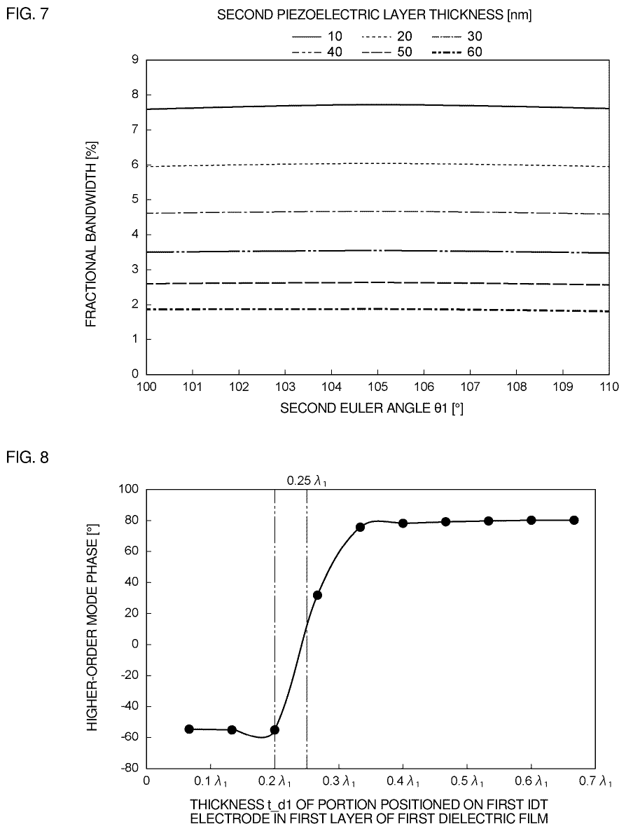

FIG. 7 is a diagram illustrating a relationship between the thickness of the second piezoelectric layer, the second Euler angle of the first piezoelectric layer, and the fractional bandwidth of the acoustic wave resonator having the same configuration as the configuration of the first acoustic wave resonator and the second acoustic wave resonator of the first example embodiment.

As illustrated in FIG. 7, as the thickness of the second piezoelectric layer 6B increases, a value of the fractional bandwidth decreases. Therefore, the thickness of the second piezoelectric layer 6B of the acoustic wave resonator 1 can be adjusted to adjust the fractional bandwidth of the acoustic wave resonator 1. On the other hand, the value of the fractional bandwidth is nearly unchanged even when the second Euler angle θ1 of the first piezoelectric layer 6A changes.

Also in each of the first acoustic wave resonator 1A and the second acoustic wave resonator 1B, which has the same configuration as that of the acoustic wave resonator 1, the thickness of the second piezoelectric layer 6B can be adjusted to adjust the fractional bandwidth.

For example, in the case in which the acoustic wave device 10 is used in the filter device, when the resonant frequency or the anti-resonant frequency of the first acoustic wave resonator 1A is close to a frequency at an end portion of a pass band of the filter device, the fractional bandwidth of the first acoustic wave resonator 1A may be narrow. In this case, steepness can be high. Herein, high steepness indicates that an amount of change in frequency is small relative to a certain constant amount of change in attenuation around the end portion of the pass band.

On the other hand, when the resonant frequency or an anti-resonant frequency of the second acoustic wave resonator 1B is far from the frequency at the end portion of the pass band of the filter device, the fractional bandwidth of the second acoustic wave resonator 1B may be wide. This easily reduces insertion loss in the pass band. In this manner, the filter device using the acoustic wave device 10 can have improved filter characteristics. In addition, an unnecessary wave can be suppressed in the first acoustic wave resonator 1A and the second acoustic wave resonator 1B. Therefore, the filter device can have further improved filter characteristics.

As in the first example embodiment, silicon oxide is preferably used as the material for the first layer 8a and the first layer 8c of the first dielectric film 8A and the second dielectric film 8B. In this case, the first IDT electrode 7A and the second IDT electrode 7B are embedded in the layers including silicon oxide as the materials. As a result, the absolute value of a temperature coefficient of frequency (TCF) in each of the first acoustic wave resonator 1A and the second acoustic wave resonator 1B can reduce. Thus, the first acoustic wave resonator 1A and the second acoustic wave resonator 1B can have improved temperature characteristics of frequency.

Silicon nitride is preferably used as the material for the second layer 8b and the second layer 8d of the first dielectric film 8A and the second dielectric film 8B. As a result, the acoustic wave device 10 can have improved moisture resistance.

The present inventor has discovered that the second Euler angle θ1 of the first piezoelectric layer 6A at which the Rayleigh wave is suppressible can be calculated based on the thickness of the second piezoelectric layer 6B and the thickness of the main electrode layer of the first IDT electrode 7A. In more detail, simulation was performed with the following examples of example design parameters of the first acoustic wave resonator 1A. Therefore, the following Equation 1 was derived. Equation 1 is a relational expression between the second Euler angle θ1 of the first piezoelectric layer 6A at which the Rayleigh wave is suppressible, and the thickness of the second piezoelectric layer 6B and the thickness of the main electrode layer of the first IDT electrode 7A.

Support substrate: material . . . Si, thickness . . . 100 μm, azimuth . . . (111), Euler angles (φ, θ, ψ) . . . (−45 °, −54.7 °, 73 °)

First intermediate layer: material . . . SiN, thickness . . . 50 nm

Second intermediate layer: material . . . SiO₂, thickness . . . 400 nm

First piezoelectric layer: material . . . LiNbO₃, thickness . . . 300 nm, Euler angles (φ1, θ1, ψ1) . . . (0 °, θ1, 0 °), second Euler angle θ1 . . . changed within a range of 90 °or more and 110 °or less

Second piezoelectric layer: material . . . LiNbO₃, thickness . . . 10 nm, 30 nm, or 50 nm, Euler angles (φ2, θ2, ψ2) . . . (0 °, θ2, 0 °), second Euler angle θ2 . . . θ1-180 °and changed within a range of −90 °or more and −70 °or less

First IDT electrode: material . . . NiCr/Pt/Ti/Al/Ti from the second piezoelectric layer side, thickness . . . 10 nm/ 10 nm, 30 nm, or 50 nm/30 nm/150 nm/10 nm from the second piezoelectric layer side, duty ratio . . . 0.5, the number of pairs of electrode fingers . . . 100 pairs

Wavelength λ₁: 1 μm

Intersecting width: 20 λ₁

First layer of first dielectric film: material . . . SiO₂, thickness . . . 330 nm

Second layer of first dielectric film: material . . . SiN, thickness 30 nm

In the following Equation 1, assume that the thickness of the main electrode layer of the first IDT electrode 7A is t_IDT [μm], and the thickness of the portion of the second piezoelectric layer 6B provided with the first IDT electrode 7A is t_piezo [μm]. Theta [°] as an angle represented by Equation 1 is the second Euler angle θ1 of the first piezoelectric layer 6A at which the Rayleigh wave is suppressed.

Theta=102.5+125×(t_piezo[μm]−0.03)−125×(t_IDT[μm]−0.03)+6250×((t_piezo[μm]−0.03)×(t_IDT[μm]−0.03)) . . . Equation 1

When the Euler angles (φ1, θ1, ψ1) of the first piezoelectric layer 6A are (0 °, θ1, 0 °), by the second Euler angle θ1 being the angle Theta in Equation 1, the Rayleigh wave can effectively be suppressed in the first acoustic wave resonator 1A.

In Equation 1, the angle Theta depends on the thickness of the second piezoelectric layer 6B. The first acoustic wave resonator 1A and the second acoustic wave resonator 1B have different thicknesses of the second piezoelectric layer 6B. The angle Theta does not change largely even when the thickness of the second piezoelectric layer 6B changes. This is also apparent based on that, as illustrated in FIGS. 6 and 7, the second Euler angle θ1 at which the Rayleigh wave is suppressed does not change largely even when the thickness of the second piezoelectric layer 6B changes. Thus, by the Euler angles (φ1, θ1, ψ1) of the first piezoelectric layer 6A being (0 °, θ1, 0 °) and the second Euler angle θ1 being the angle Theta, the Rayleigh wave can effectively be suppressed in the first acoustic wave resonator 1A and the second acoustic wave resonator 1B.

As a result of further examination, it has become apparent that in a case in which the first Euler angle φ1 is within a range of about 0 °±5 °and the third Euler angle ψ1 is within a range of about 0 °±5 °, the same effect as that described above is achievable when the second Euler angle θ1 is within a range of Theta ± about 10 °, for example. Therefore, it is preferable that the Euler angles (φ1, θ1, ψ1) of the first piezoelectric layer 6A are (about 0 °±5 °, θ1, about 0 °±5 °) and the second Euler angle θ1 is within the range of Theta ±about 10 °, for example. Thus, the Rayleigh wave can effectively be suppressed in the first acoustic wave resonator 1A and the second acoustic wave resonator 1B.

In the first example embodiment, lithium niobate is used as the material for the first piezoelectric layer 6A and the second piezoelectric layer 6B. Note that also in a case in which lithium tantalate is used as the material for the first piezoelectric layer 6A and the second piezoelectric layer 6B, the Euler angles (φ1, θ1, ψ1) of the first piezoelectric layer 6A are preferably within the above-described range. That is, it is preferable that the Euler angles (φ1, θ1, ψ1) of the first piezoelectric layer 6A are (about 0 °±5 °, θ1, about 0 °±5 °) and the second Euler angle θ1 is within the range of Theta±about 10 °, for example. Also in this case, the Rayleigh wave can effectively be suppressed in the first acoustic wave resonator 1A and the second acoustic wave resonator 1B.

In the following description, as illustrated in FIG. 2, the thickness of a portion of the layer covering the first IDT electrode 7A in the first dielectric film 8A, the portion being positioned on the first IDT electrode 7A, is assumed to be t_d1. In the first example embodiment, the layer covering the first IDT electrode 7A in the first dielectric film 8A is the first layer 8a. The thickness t_d1 of the first layer 8a is preferably less than or equal to about 0.25 λ₁, for example. Therefore, a higher-order mode can be suppressed in the first acoustic wave resonator 1A. Details will be described below.

Simulation was performed with the following examples of design parameters of the first acoustic wave resonator 1A. Therefore, a range of the thickness t_d1 of the first layer 8a of the first dielectric film 8A within which the higher-order mode was suppressible was derived.

Support substrate: material . . . Si, thickness . . . 100 μm, azimuth . . . (111), Euler angles (φ, θ, ψ) . . . (−45 °, −54.7 °, 73 °)

First intermediate layer: material . . . SiN, thickness . . . 50 nm

Second intermediate layer: material . . . SiO₂, thickness . . . 400 nm

First piezoelectric layer: material . . . LiNbO₃, thickness . . . 300 nm, Euler angles (φ1, θ1, ψ1) . . . (0 °, 105 °, 0 °)

Second piezoelectric layer: material . . . LiNbO₃, thickness . . . 10 nm, Euler angles (φ2, θ2, ψ2) . . . (0 °, −75 °, 0 °)

First IDT electrode: material . . . NiCr/Pt/Ti/Al/Ti from the second piezoelectric layer side, thickness . . . 10 nm/30 nm/30 nm/150 nm/10 nm from the second piezoelectric layer side, duty ratio . . . 0.5, the number of pairs of electrode fingers . . . 100 pairs

Wavelength λ₁: 1.5μm

Intersecting width: 20 λ₁

First layer of first dielectric film: material . . . SiO₂, thickness t_d1 . . . changed every 100 nm within a range of 100 nm or more and 1000 nm or less, and when converted into wavelength λ₁, changed every 0.067 λ₁ within a range of 0.067 λ₁ or more and 0.667λ₁ or less, the entire thickness . . . changed every 100 nm within a range of 330 nm or more and 1230 nm or less

Second layer of first dielectric film: material . . . SiN, thickness 30 nm

FIG. 8 is a diagram illustrating a relationship between the thickness of the portion positioned on the first IDT electrode in the first layer and a phase of a higher-order mode in the first dielectric film according to the first example embodiment.

As illustrated in FIG. 8, when the thickness t_d1 of the first layer 8a of the first dielectric film 8A is larger than about 0.25 λ₁, suppression of the higher-order mode in the acoustic wave resonator 1A is insufficient. On the other hand, it can be seen that when the thickness t_d1 of the first layer 8a is less than or equal to about 0.25 λ₁, for example, the higher-order mode can be suppressed. Further, the thickness t_d1 of the first layer 8a is more preferably less than or equal to about 0.2 λ₁, for example. Therefore, the higher-order mode can be further suppressed in the first acoustic wave resonator 1A.

Similarly, also in the second acoustic wave resonator 1B, assuming that the thickness of a portion of the layer covering the second IDT electrode 7B in the second dielectric film 8B, the portion being positioned on the second IDT electrode 7B, is t_d2, the thickness t_d2 is preferably less than or equal to about 0.25 λ₂, for example. Specifically, in the first example embodiment, the layer covering the second IDT electrode 7B in the second dielectric film 8B is the first layer 8c. Therefore, the thickness t_d2 of the first layer 8c is preferably about 0.25 λ₂, for example. Thus, the higher-order mode can be suppressed in the second acoustic wave resonator 1B. The thickness t_d2 of the first layer 8c is more preferably less than or equal to about 0.2 λ₂, for example. Therefore, the higher-order mode can be further suppressed in the second acoustic wave resonator 1B.

In the case in which the acoustic wave device 10 includes a plurality of first acoustic wave resonators 1A, the thickness t_d1 of the first layer 8a of the first dielectric film 8A can be converted into the wavelength λ₁ for each first acoustic wave resonator 1A. In this case, the thickness t_d1 of the first layer 8a is preferably less than or equal to about 0.25 λ₁, and more preferably less than or equal to about 0.2 λ₁ in at least one of the first acoustic wave resonators 1A, for example. Therefore, the higher-order mode can be suppressed in at least one of the first acoustic wave resonators 1A. The thickness t_d1 of the first layer 8a is more preferably less than or equal to about 0.25 λ₁, further preferably less than or equal to about 0.2 λ₁ in all the first acoustic wave resonators 1A, for example. Therefore, the higher-order mode can be suppressed in all the first acoustic wave resonators 1A.

The same applies to a case in which the acoustic wave device 10 includes a plurality of second acoustic wave resonators 1B. Specifically, the thickness t_d2 of the first layer 8c of the second dielectric film 8B can be converted into the wavelength λ₂ for each second acoustic wave resonator 1B. In this case, the thickness t_d2 of the first layer 8c is preferably less than or equal to about 0.25 λ₂, more preferably less than or equal to about 0.2 λ₂ in at least one of the second acoustic wave resonators 1B, for example. Therefore, the higher-order mode can be suppressed in at least one of the second acoustic wave resonators 1B. The thickness t_d2 of the first layer 8c is more preferably less than or equal to about 0.25 λ₂, further preferably less than or equal to about 0.2 λ₂ in all the second acoustic wave resonators 1B, for example. Therefore, the higher-order mode can be suppressed in all the second acoustic wave resonators 1B.

An example of the materials for the respective layers of the support 2, the first piezoelectric layer 6A, and the second piezoelectric layer 6B will be described below. Herein, a main constituent indicates a constituent that accounts for more than about 50 wt % of a member. A material of the main constituent may be present in a form of either single crystalline, polycrystalline, or amorphous, or a form of mixture thereof.

Examples of the material that can be used for the support substrate 3 include: piezoelectric materials, such as aluminum nitride, lithium tantalate, lithium niobate, and crystal; ceramics, such as alumina, sapphire, magnesia, silicon nitride, silicon carbide, zirconia, cordierite, mullite, steatite, forsterite, spinel, and sialon; dielectrics, such as aluminum oxide, silicon oxynitride, diamond-like carbon (DLC), and diamond; semiconductors, such as silicon; and materials including the above-described material as a main constituent. The spinel includes an aluminum compound including one or more elements selected from Mg, Fe, Zn, Mn, and the like, and oxygen. Examples of the spinel include MgAl₂O₄, FeAl₂O₄, ZnAl₂O₄, and MnAl₂O₄. The same applies to spinel described later as an example of the material for the first intermediate layer 4. In the first example embodiment, the support substrate 3 is a silicon support substrate.

In the first example embodiment, the first intermediate layer 4 is a high-acoustic-velocity film. The high-acoustic-velocity film is a film in which an acoustic velocity of a bulk wave being propagated is relatively high. More specifically, an acoustic velocity of a bulk wave being propagated in the high-acoustic-velocity film is higher than an acoustic velocity of an acoustic wave being propagated in the first piezoelectric layer 6A and the second piezoelectric layer 6B. Examples of the material that can be used for the first intermediate layer 4, which is the high-acoustic-velocity film, include: piezoelectric materials, such as aluminum nitride, lithium tantalate, lithium niobate, and crystal; ceramics, such as alumina, sapphire, magnesia, silicon nitride, silicon carbide, zirconia, cordierite, mullite, steatite, forsterite, spinel, and sialon; dielectrics, such as aluminum oxide, silicon oxynitride, diamond-like carbon (DLC), and diamond; semiconductors, such as silicon; and materials including the above-described material as a main constituent. In the first example embodiment, the first intermediate layer 4 is a silicon nitride layer.

On the other hand, the second intermediate layer 5 is a low-acoustic-velocity film. The low-acoustic-velocity film is a film in which an acoustic velocity of a bulk wave being propagated is relatively low. More specifically, an acoustic velocity of a bulk wave being propagated in the low-acoustic-velocity film is lower than an acoustic velocity of a bulk wave being propagated in the first piezoelectric layer 6A and the second piezoelectric layer 6B. Examples of the material that can be used for the second intermediate layer 5, which is the low-acoustic-velocity film, include: dielectrics, such as glass, silicon oxide, silicon oxynitride, lithium oxide, tantalum oxide, and a compound in which fluorine, carbon, or boron is added to silicon oxide; and materials including the above-described material as the main constituent. In the first example embodiment, the second intermediate layer 5 is a silicon oxide layer.

Examples of the material that can be used for the first piezoelectric layer 6A and the second piezoelectric layer 6B include lithium tantalate and lithium niobate. In the first example embodiment, both of the first piezoelectric layer 6A and the second piezoelectric layer 6B are lithium niobate layers. The polarization direction of the first piezoelectric layer 6A is different from the polarization direction of the second piezoelectric layer 6B.

In the acoustic wave device 10, the first intermediate layer 4, which is the high-acoustic-velocity film, the second intermediate layer 5, which is the low-acoustic-velocity film, the first piezoelectric layer 6A, and the second piezoelectric layer 6B are stacked in this order. Therefore, energy of an acoustic wave can effectively be confined on the first piezoelectric layer 6A side and the second piezoelectric layer 6B side. Note that the support 2 does not necessarily include the first intermediate layer 4 and the second intermediate layer 5.

In the first example embodiment of the present invention, all the acoustic wave resonators in the acoustic wave device 10 share the second piezoelectric layer 6B. Note that one or some of the acoustic wave resonators in the acoustic wave device 10 do not necessarily include the second piezoelectric layer 6B. Such example is described according to a second example embodiment of the present invention.

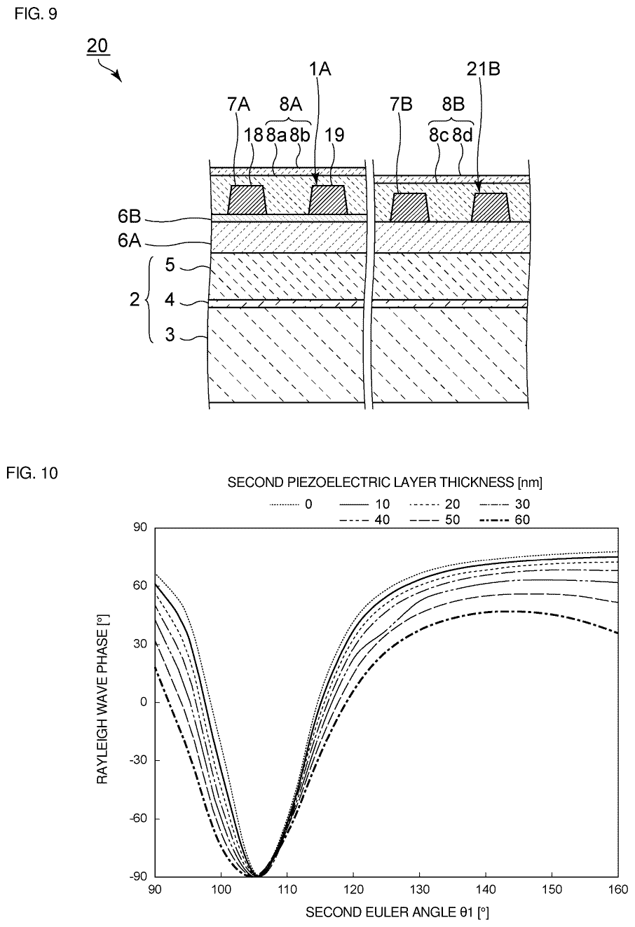

FIG. 9 is a schematic elevational cross-sectional view of surroundings of a pair of electrode fingers of a first acoustic wave resonator and surroundings of a pair of electrode fingers of a second acoustic wave resonator according to the second example embodiment.

This example embodiment is different from the first example embodiment in that a second acoustic wave resonator 21B does not include the second piezoelectric layer 6B. In an acoustic wave device 20 of this example embodiment, configurations other than the above-described configuration are the same as those of the acoustic wave device 10 of the first example embodiment.

The second acoustic wave resonator 21B shares the support 2 and the first piezoelectric layer 6A with the first acoustic wave resonator 1A. On the other hand, the second acoustic wave resonator 21B does not share the second piezoelectric layer 6B with the first acoustic wave resonator 1A. The second acoustic wave resonator 21B includes the second IDT electrode 7B and the second dielectric film 8B. In the second acoustic wave resonator 21B, the second IDT electrode 7B is provided directly on the first piezoelectric layer 6A. The second dielectric film 8B is provided directly on the first piezoelectric layer 6A to cover the second IDT electrode 7B. The second IDT electrode 7B is embedded in the second dielectric film 8B.

In the second acoustic wave resonator 21B, a distance between the second IDT electrode 7B and the first piezoelectric layer 6A is zero. On the other hand, in the first acoustic wave resonator 1A, the first IDT electrode 7A is provided indirectly on the first piezoelectric layer 6A with the second piezoelectric layer 6B interposed therebetween. Therefore, a value of a distance between the first IDT electrode 7A and the first piezoelectric layer 6A is the same as the value of the thickness of the second piezoelectric layer 6B. In this manner, the distance between the first piezoelectric layer 6A and the first IDT electrode 7A is different from the distance between the first piezoelectric layer 6A and the second IDT electrode 7B.

In this example embodiment, a plurality of acoustic wave resonators in the acoustic wave device 20 include the first acoustic wave resonator 1A with the second piezoelectric layer 6B and the second acoustic wave resonator 21B without the second piezoelectric layer 6B. Also in this case, the Rayleigh wave, which is an unnecessary wave, can be suppressed in the plurality of acoustic wave resonators in the acoustic wave device 20. This will be described below.

In the first acoustic wave resonator 1A, a relationship between the second Euler angle θ1 of the first piezoelectric layer 6A and the phase of the Rayleigh wave was simulated for each different thickness of the second piezoelectric layer 6B. Also in the second acoustic wave resonator 21B, a relationship between the second Euler angle θ1 of the first piezoelectric layer 6A and the phase of the Rayleigh wave was simulated. Examples of design parameters of the first acoustic wave resonator 1A are as follows.

Support substrate: material . . . Si, thickness . . . 100 μm, azimuth . . . (111), Euler angles (φ, θ, ψ) . . . (−45 °, −54.7 °, 73 °)

First intermediate layer: material . . . SiN, thickness . . . 50 nm

Second intermediate layer: material . . . SiO₂, thickness . . . 400 nm

First piezoelectric layer: material . . . LiNbO₃, thickness . . . 300 nm, Euler angles (φ1, θ1, ψ1) . . . (0 °, θ1, 0 °), second Euler angle θ1 . . . changed every 0.5 °within a range of 90 °or more and 160 °or less

Second piezoelectric layer: material . . . LiNbO₃, thickness . . . changed every 10 nm within a range of 10 nm or more and 60 nm or less, Euler angles (φ2, θ2, ψ2) . . . (0 °, θ2, 0 °), second Euler angle θ2 . . . θ1-180 °and changed every 0.5 °within a range of −90 °or more and −20 °or less

First IDT electrode: material . . . NiCr/Pt/Ti/Al/Ti from the second piezoelectric layer side, thickness . . . 10 nm/30 nm/30 nm/150 nm/10 nm from the second piezoelectric layer side, duty ratio . . . 0.5, the number of pairs of electrode fingers . . . 100 pairs

Wavelength λ₁: 1.3 μm

Intersecting width: 20 λ₁

First layer of first dielectric film: material . . . SiO₂, thickness . . . 330 nm

Second layer of first dielectric film: material . . . SiN, thickness 30 nm

Example design parameters of the second acoustic wave resonator 21B were the same as those of the first acoustic wave resonator 1A except that the thickness of the second piezoelectric layer 6B was zero, that is, the second piezoelectric layer 6B was not provided.

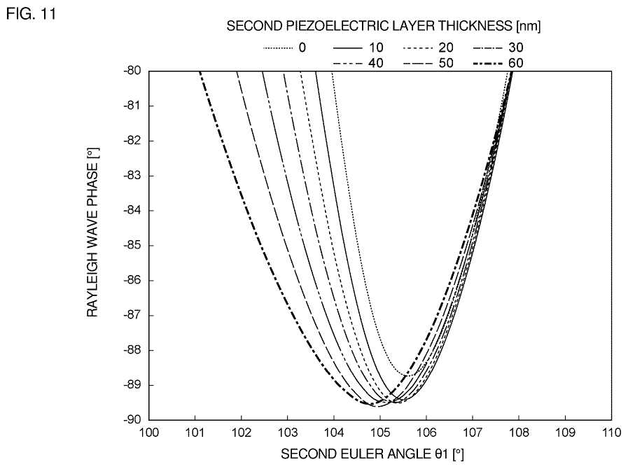

FIG. 10 is a diagram illustrating a relationship between the thickness of the second piezoelectric layer, the second Euler angle of the first piezoelectric layer, and the phase of the Rayleigh wave of the first acoustic wave resonator and the second acoustic wave resonator according to the second example embodiment. FIG. 11 is a partially enlarged view of FIG. 10.

As illustrated in FIGS. 10 and 11, the second Euler angle θ1 of the first piezoelectric layer 6A at which the Rayleigh wave is suppressible is nearly unchanged between the case in which the thickness of the second piezoelectric layer 6B is not zero and the case in which the thickness of the second piezoelectric layer 6B is zero. Therefore, the second Euler angle θ1 of the first piezoelectric layer 6A at which the Rayleigh wave is suppressible is nearly unchanged between the first acoustic wave resonator 1A with the second piezoelectric layer 6B and the second acoustic wave resonator 21B without the second piezoelectric layer 6B. Thus, the Rayleigh wave, which is an unnecessary wave, can be suppressed in the first acoustic wave resonator 1A and the second acoustic wave resonator 21B as the plurality of acoustic wave resonators in the acoustic wave device 20.

While example embodiments of the present invention have been described above, it is to be understood that variations and modifications will be apparent to those skilled in the art without departing from the scope and spirit of the present invention. The scope of the present invention, therefore, is to be determined solely by the following claims.

What is claimed is:

1. An acoustic wave device comprising:
at least one first acoustic wave resonator including:
a first piezoelectric layer;
a second piezoelectric layer provided on the first piezoelectric layer;
a first IDT electrode provided on the second piezoelectric layer and including a plurality of electrode fingers; and
a first dielectric film provided on the second piezoelectric layer to cover the first IDT electrode; and
at least one second acoustic wave resonator that shares the first piezoelectric layer with the first acoustic wave resonator, the at least one second acoustic wave resonator including:
a second IDT electrode provided directly or indirectly on the first piezoelectric layer and including a plurality of electrode fingers; and
a second dielectric film provided directly or indirectly on the first piezoelectric layer to cover the second IDT electrode; wherein
a distance between the first piezoelectric layer and the first IDT electrode is different from a distance between the first piezoelectric layer and the second IDT electrode;
a polarization direction of the first piezoelectric layer is different from a polarization direction of the second piezoelectric layer; and
the first IDT electrode is embedded in the first dielectric film and the second IDT electrode is embedded in the second dielectric film.

2. The acoustic wave device according to claim 1, wherein
the second acoustic wave resonator shares the second piezoelectric layer with the first acoustic wave resonator;
the second IDT electrode and the second dielectric film are provided on the second piezoelectric layer; and
in the second piezoelectric layer, a thickness of a portion of the first IDT electrode is different from a thickness of a portion of the second IDT electrode.

3. The acoustic wave device according to claim 1, wherein
the second IDT electrode is provided directly on the first piezoelectric layer; and
the second dielectric film is provided directly on the first piezoelectric layer to cover the second IDT electrode.

4. The acoustic wave device according to claim 1, wherein when Euler angles of the first piezoelectric layer are (φ1, θ1, ψ1), and Euler angles of the second piezoelectric layer are (φ2, θ2, 104 2), a difference between the angle θ1 in the Euler angles (φ1, θ1, ψ1) of the first piezoelectric layer and the angle θ2 in the Euler angles (φ2, θ2, ψ2) of the second piezoelectric layer is within a range of about 180 °±5 °.

5. The acoustic wave device according to claim 1, wherein a material for the first piezoelectric layer includes lithium niobate or lithium tantalate.

6. The acoustic wave device according to claim 5, wherein
the first IDT electrode includes at least one metal layer, and the first IDT electrode includes a main electrode layer that is more than about 50 wt % of an entirety of the metal layer;
when Euler angles of the first piezoelectric layer are (φ1, θ1, ψ1), the Euler angles (φ1, θ1, ψ1) of the first piezoelectric layer are (about 0 °±5 °, θ1, about 0 °±5 °); and
when a thickness of the main electrode layer of the first IDT electrode is t_IDT [μm], a thickness of a portion of the second piezoelectric layer provided with the first IDT electrode is t_piezo [μm], and an angle represented by Equation 1 defined below is Theta [°], the angle θ1 in the Euler angles (about 0 °±5 °, θ1, about 0 °±5 °) of the first piezoelectric layer is within a range of Theta±10 °:
Theta=102.5+125×(t_piezo[μm]−0.03)−125×(t_IDT[μm]−0.03)+6250×((t_piezo[μm]−0.03)×(t_IDT[μm]−0.03)) . . . Equation 1.

7. The acoustic wave device according to claim 1, wherein when a wavelength defined by an electrode finger pitch of the first IDT electrode is λ₁, a thickness of a portion of a layer covering the first IDT electrode in the first dielectric film, the portion being positioned on the first IDT electrode, is less than or equal to about 0.25 λ₁.

8. The acoustic wave device according to claim 1, wherein the first dielectric film includes a layer including silicon oxide as a material, and the first IDT electrode is embedded in the layer.

9. The acoustic wave device according to claim 1, wherein the first dielectric film and the second dielectric film are made of a same material and provided integrally.

10. The acoustic wave device according to claim 1, wherein each of the first and second IDT electrodes includes a plurality of metal layers.

11. The acoustic wave device according to claim 1, wherein each of the first and second IDT electrodes includes a NiCr layer, a Pt layer, a Ti layer, an Al layer, and a Ti layer.

12. The acoustic wave device according to claim 1, wherein the at least one first acoustic wave resonator includes a pair of reflectors, and the at least one second acoustic wave resonator includes a pair of reflectors.

13. The acoustic wave device according to claim 1, wherein each of the first dielectric film and the second dielectric film includes a plurality of layers.

14. The acoustic wave device according to claim 13, wherein a first layer of the first dielectric film and a first layer of the second dielectric film includes silicon oxide, and a second layer of the first dielectric film and a second layer of the second dielectric film includes silicon nitride.

15. The acoustic wave device according to claim 1, further comprising a support shared by the at least one first acoustic wave resonator and the at least one second acoustic wave resonator.

16. The acoustic wave device according to claim 15, wherein the support includes a support substrate.

17. The acoustic wave device according to claim 16, wherein the support further includes a first intermediate layer on the support substrate, and a second intermediate layer on the first intermediate layer.

18. The acoustic wave device according to claim 17, wherein the support substrate includes silicon, the first intermediate layer includes silicon nitride, the second intermediate layer includes silicon oxide, the first piezoelectric layer includes lithium niobate, and the second piezoelectric layer includes lithium niobate.

19. The acoustic wave device according to claim 1, wherein the first and second dielectric films have different thicknesses.

20. The acoustic wave device according to claim 17, wherein the first intermediate layer is a high-acoustic-velocity film and the second intermediate layer is a low-acoustic-velocity film.
